(19) United States
(12) Patent Application Publication
(10) Pub. No.: US 2015/0333047 A1
(43) Pub. Date: Nov. 19, 2015

(54) METHOD FOR PRODUCING OPTOELECTRONIC SEMICONDUCTOR CHIPS, AND OPTOELECTRONIC SEMICONDUCTOR CHIP

(71) Applicant: OSRAM OPTO SEMICONDUCTORS GMBH, Regensburg (DE)

(72) Inventor: Alexander F. PFEUFFER, Regensburg (DE)

(21) Appl. No.: 14/653,839

(22) PCT Filed: Dec. 12, 2013
(86) PCT No.: PCT/EP2013/076355

§ 371 Date: Jun. 18, 2015

(30) Foreign Application Priority Data
Dec. 18, 2012 (DE) 10 2012 112 530.9

(51) Int. Cl. H01L 25/16; H01L 33/00; H01L 31/18; H01L 27/146; H01L 27/15

(52) U.S. Cl. CPC H01L 25/167; H01L 27/146; H01L 27/156; H01L 27/14687; H01L 31/18; H01L 33/005

(57) ABSTRACT

What is specified is a method for producing a plurality of optoelectronic semiconductor chips (1) each having a plurality of pixels (25). A semiconductor layer sequence (2) having an active region (20) provided for generating and/or detecting radiation, said active region being formed between a first semiconductor layer (21) a second semiconductor layer (22), is provided. The semiconductor layer sequence is fixed to a carrier (5) with a plurality of first connection areas (51), such that the first semiconductor layer is electrically conductively connected to the first connection areas. Isolating trenches (27) are formed in the semiconductor layer sequence fixed to the carrier, in order to form the pixels, wherein the isolating trenches extend through the semiconductor layer sequence. A contact layer (6) is formed, which electrically conductively connects the second semiconductor layer to a second connection area (52) of the carrier. The carrier is singulated into the plurality of semiconductor chips each having a plurality of pixels. Furthermore, an optoelectronic semiconductor chip (1) is specified.

The present application relates to a method for producing a plurality of optoelectronic chips, each of which comprises a plurality of pixels, and to such an optoelectronic semiconductor chip.

For the production of display devices based on light-emitting diodes, stringent requirements are placed on the alignment accuracy, for example for the positioning of the radiation-emitting layers relative to a driver circuit for the display device.

It is an object to provide a method with which optoelectronic semiconductor chips, each of which comprises a plurality of pixels, can be produced in a straightforward and reliable way. An optoelectronic semiconductor chip which is distinguished by good drivability of the individual pixels is furthermore intended to be provided.

These objects are respectively achieved inter alia by a method and by an optoelectronic semiconductor chip according to the independent patent claims. The dependent patent claims relate to configurations and refinements.

In the method, a plurality of optoelectronic semiconductor chips are produced, each of which comprises a plurality of pixels.

According to at least one embodiment of the method, a semiconductor layer sequence having an active region intended to generate and/or detect radiation, which is formed between a first semiconductor layer and a second semiconductor layer, is provided. The first semiconductor layer is expediently different to the second semiconductor layer in terms of conduction type. For example, the first semiconductor layer is p-conductive and the second semiconductor layer is n-conductive, or vice versa. For example, the semiconductor layer sequence is intended to generate and/or detect radiation in the infrared, visible or ultraviolet spectral range.

According to at least one embodiment of the method, a carrier having a plurality of first connection surfaces is provided. The carrier may furthermore comprise at least one second connection surface. Preferably, a control circuit for driving the pixels of the finally produced semiconductor chip is integrated into the carrier. During operation of the finally produced semiconductor chip, charge carriers can be injected through the first connection surface assigned to the pixel and the second connection surface on opposite sides of the active region into the active region, and recombine there so as to emit radiation. In the case of a radiation receiver, charge carriers generated in the active region by radiation absorption can be extracted from the active region. The control circuit is preferably configured as an active matrix circuit, so that each pixel is individually drivable and a plurality of pixels, in particular all the pixels, can be operated simultaneously.

According to at least one embodiment of the method, the semiconductor layer sequence is fastened on the carrier. In particular, the first semiconductor layer is electrically conductively connected to the first connection surfaces. Preferably, the first semiconductor layer extends continuously over several first connection surfaces, in particular over the entire area of all the first connection surfaces. The first semiconductor layer may thus be fastened in an unstructured form on the carrier. In particular, the first semiconductor layer can connect at least one first connection surface and a second connection surface electrically conductively to one another after fastening on the carrier. The electrical isolation of the connection surfaces, which is required for operation, is carried out in a later stage of the method.

According to at least one embodiment of the method, separating trenches are formed in the semiconductor layer sequence in order to form the pixels, the separating trenches extending in particular through the semiconductor layer sequence. For example, the separating trenches may extend fully through the semiconductor layer sequence in the vertical direction. The vertical direction is a direction which extends perpendicularly to a main extent plane of the semiconductor layers of the semiconductor layer sequence. For example, the separating trenches are formed by means of wet chemical etching or dry chemical etching.

According to at least one embodiment of the method, the separating trenches are formed after the semiconductor layer sequence is already fastened on the carrier. The pixels are thus not defined until after the semiconductor layer sequence is fastened on the carrier. In particular, the pixels are not formed until after at least one semiconductor layer of the semiconductor layer sequence is already connected electrically conductively to the first connection surface of the carrier, and in particular to the control circuit integrated into the carrier.

According to at least one embodiment of the method, a contact layer is formed. The contact layer connects the second semiconductor layer electrically conductively to the second connection surface of the carrier. The carrier comprises, in particular, at least one second connection surface for each semiconductor chip. For example, the carrier respectively comprises one second connection surface for each pixel.

According to at least one embodiment of the method, the carrier is singulated into the plurality of semiconductor chips, the semiconductor chips respectively comprising a plurality of pixels. Expediently, the singulation of the carrier into semiconductor chips takes place after the semiconductor layer sequence is already fastened on the carrier and is electrically conductively connected to the carrier by means of the contact layer.

In at least one embodiment of the method, a semiconductor layer sequence having an active region intended to generate and/or detect radiation, which is formed between a first semiconductor layer and a second semiconductor layer, is provided. A carrier having a plurality of first connection surfaces is provided. The semiconductor layer sequence is fastened on the carrier so that the first semiconductor layer is electrically conductively connected to the first connection surfaces. In order to form the pixels, separating trenches are formed in the semiconductor layer sequence fastened on the carrier, the separating trenches extending through the semiconductor layer sequence. A contact layer, which connects the second semiconductor layer electrically conductively to a second connection surface of the carrier, is formed. The carrier is singulated into the plurality of semiconductor chips, each of which comprises a plurality of pixels. In particular, the production of the semiconductor chips is carried out in the wafer assembly, and the wafer assembly is cut up in the singulation step.

The fastening of the semiconductor layer sequence on the carrier, the formation of the separating trenches, the formation of the contact layer and the singulation of the carrier are preferably carried out in the order indicated. The separating trenches are thus not formed until after the semiconductor layer sequence is already fastened on the carrier. Finely adjusted positioning of already formed pixels of a semiconductor layer sequence relative to the associated connection surfaces of a carrier can thus be obviated. The term “finely adjusted” is intended to mean in particular that the maximum deviation of the accuracy of the positioning is at most as large, preferably at most half as large, as a center spacing between two neighboring pixels.

According to at least one embodiment of the method, the semiconductor layer sequence is free of recesses at least in the region, from which the semiconductor chips are formed, during fastening on the carrier. In other words, the semiconductor layer sequence is unstructured in the lateral direction, i.e. in a direction extending along the main extent plane of the semiconductor layers of the semiconductor layer sequence. In particular, no photolithographic step for removing material of the semiconductor layer sequence is carried out in order to form separating trenches between the pixels before the semiconductor layer sequence is fastened on the carrier.

According to at least one embodiment of the method, alignment during the formation of the separating trenches is carried out relative to alignment marks, which are formed on the carrier. For example, a mask for the photolithography to define the separating trenches on the side of the semiconductor layer sequence facing away from the carrier can be positioned relative to the alignment marks. Finely adjusted formation of the pixels relative to the associated connection surfaces of the carrier is thereby simplified.

According to at least one embodiment of the method, the semiconductor layer sequence is provided with a metal interlayer before fastening on the carrier. The metal interlayer may be formed in one layer or a plurality of layers. In particular, the metal interlayer directly adjoins the semiconductor layer sequence. For example, the metal interlayer is applied onto the prefabricated semiconductor layer sequence by means of vapor deposition or sputtering.

According to at least one embodiment of the method, the metal interlayer is cut through after the semiconductor layer sequence is fastened on the carrier and before the carrier is singulated into the semiconductor chips. In particular, the metal interlayer is cut through in the region of the separating trenches, so that neighboring pixels are not electrically conductively connected to one another by the metal interlayer.

As an alternative or in addition, the metal interlayer is cut through in the region of the second connection surfaces. The application of the contact layer may be carried out in the region of the second connection surfaces exposed in this way.

According to at least one embodiment of the method, alignment windows are formed in the metal interlayer before the semiconductor layer sequence is fastened on the carrier. The alignment windows extend through the metal interlayer, in particular fully, in the vertical direction. A cross-sectional area of the alignment windows is preferably larger than the cross-sectional area of the alignment marks.

During the fastening of the semiconductor layer sequence on the carrier, the semiconductor layer sequence is in particular positioned in such a way that the alignment marks on the carrier overlap with the alignment windows. For example, the positioning is carried out in such a way that the alignment marks are respectively arranged fully inside the alignment windows. By means of the alignment windows, the alignment marks are visually identifiable through the metal interlayer.

According to at least one embodiment of the method, the semiconductor layer sequence is deposited epitaxially on a growth substrate. For example, the semiconductor layer sequence may be deposited by an MOCVD or MBE method. The growth substrate is, in particular, removed from the semiconductor layer sequence before the separating trenches are formed. For example, the removal of the growth substrate is carried out after the semiconductor layer sequence is fastened on the carrier and before the separating trenches are formed in the semiconductor layer sequence. The growth substrate may, for example, be removed mechanically, for instance by means of grinding, lapping or polishing, and/or chemically, for instance by means of wet chemical or dry chemical etching. As an alternative, a laser lift-off (LLO) method may be used.

The growth substrate and the carrier are preferably matched to one another in terms of their thermal expansion coefficient, that is to say the thermal expansion coefficients differ from one another at most by 10%. Particularly preferably, the growth substrate and the carrier contain the same material. In particular, silicon is suitable. It is, however, also possible to use a different material, for example silicon carbide, gallium arsenide or sapphire.

According to at least one embodiment, an optoelectronic semiconductor chip comprises a semiconductor layer sequence having an active region intended to generate and/or receive radiation, which is arranged between a first semiconductor layer and a second semiconductor layer. The semiconductor layer sequence is subdivided into a plurality of pixels.

According to at least one embodiment of the optoelectronic semiconductor chip, the semiconductor chip comprises a carrier, on which the semiconductor layer sequence is arranged and which comprises a driver circuit for the individual pixels. The driver circuit is, in particular, configured as an active matrix circuit.

According to at least one embodiment of the semiconductor chip, the carrier comprises, for each pixel, a first connection surface which is electrically conductively connected to the first semiconductor layer of the pixels.

According to at least one embodiment, the second semiconductor layer is connected electrically conductively to a second connection surface of the carrier by a contact layer. In particular the contact layer covers a radiation transmission surface of the semiconductor layer sequence facing away from the carrier at least in regions.

In at least one embodiment of the semiconductor chip, the semiconductor chip comprises a semiconductor layer sequence, which comprises an active region intended to generate and/or receive radiation, the active region being arranged between a first semiconductor layer and a second semiconductor layer. The semiconductor layer sequence is subdivided into a plurality of pixels. The semiconductor chip comprises a carrier, on which the semiconductor layer sequence is arranged and which comprises a driver circuit for the individual pixels. The carrier has, for each pixel, a first connection surface which is electrically conductively connected to the first semiconductor layer of the pixels. The second semiconductor layer is connected electrically conductively to a second connection surface by a contact layer, the contact layer covering a radiation transmission surface facing away from the carrier at least in regions.

According to at least one embodiment of the semiconductor chip, the pixels of the semiconductor layer sequence taper in the vertical direction at least in regions with an increasing distance from the carrier. The base area of the pixels, facing toward the carrier, is thus greater than the base area of the radiation transmission surface. Pixels having such a shape can be produced during production by forming separating trenches by means of wet chemical etching, after the semiconductor layer sequence is already fastened on the carrier. It is, however, also possible to use a different method, for example a dry chemical etching method or mechanical back sputtering.

According to at least one embodiment of the semiconductor chip, the second semiconductor layer of each pixel is respectively connected electrically conductively by the contact layer to at least one second connection surface assigned to the pixel. Each pixel is thus assigned a first connection surface and a second connection surface, so that the pixels can be electrically contacted fully independently of one another.

According to at least one embodiment of the semiconductor chip, the first connection surface extends around the at least one second connection surface. For example, the first connection surface is configured in the form of a frame. Each pixel may also be assigned two or more second connection surfaces.

According to at least one embodiment of the semiconductor chip, the at least one second connection surface is arranged in an edge region or in a corner region of the first connection surface. This means that the first connection surface has, on at least one side surface or in at least one corner, an indentation in which the first connection surface is at a larger distance from the edge of the pixel than at at least one other position of the first connection surface.

According to at least one embodiment of the semiconductor chip, the first connection surface extends at least along two edges of the second connection surface. In particular, the first connection surface may extend fully around the second connection surface. A connection surface extending along two edges may, for example, be configured with an L-shape.

According to at least one embodiment of the semiconductor chip, each pixel comprises at least one cutout in the semiconductor layer sequence. The contact layer extends from the second connection surface through the cutout to the second semiconductor layer. The cutout is thus used for electrical contacting of the second semiconductor layer. In particular, the contact layer is placed over a side surface of the cutout.

According to at least one embodiment of the semiconductor chip, the second semiconductor layers of at least two neighboring pixels are electrically conductively connected to one another by the contact layer. In particular, the contact layer may form a common contact layer for all the pixels. The contact layer, or at least one sublayer of the contact layer, may fully cover the pixels. As an alternative, the contact layer may also respectively comprise a radiation window, through which the radiation to be generated or received during operation passes, on the radiation transmission surfaces of the pixels.

According to at least one embodiment of the semiconductor chip, the pixels are separated from one another by separating trenches, the contact layer extending in regions in the separating trenches. In particular, the contact layer may be configured so as to not transmit radiation in the separating trenches.

According to at least one embodiment of the semiconductor chip, the contact layer comprises a metal layer, which extends in the form of a grid in the separating trenches. A surface, facing away from the carrier, of the metal layer in the separating trenches may be formed between the carrier and the radiation transmission surface. As an alternative, the metal layer may extend beyond the semiconductor layer sequence in the vertical direction and be arranged on the radiation transmission surface of the pixels.

According to at least one embodiment of the semiconductor chip, the contact layer comprises a TCO material. TCO materials are transparent conductive oxides, for example indium tin oxide (ITO), tin oxide (SnO) or zinc oxide (ZnO). Such a contact layer may cover the radiation transmission surfaces of the pixels over a large area or even fully.

In particular, the method described above is suitable for production of the semiconductor chip described. Features mentioned in connection with the method may therefore also be employed for the semiconductor chip, and vice versa.

Further features, configurations and expediencies may be found in the following description of the exemplary embodiments in conjunction with the figures, in which:

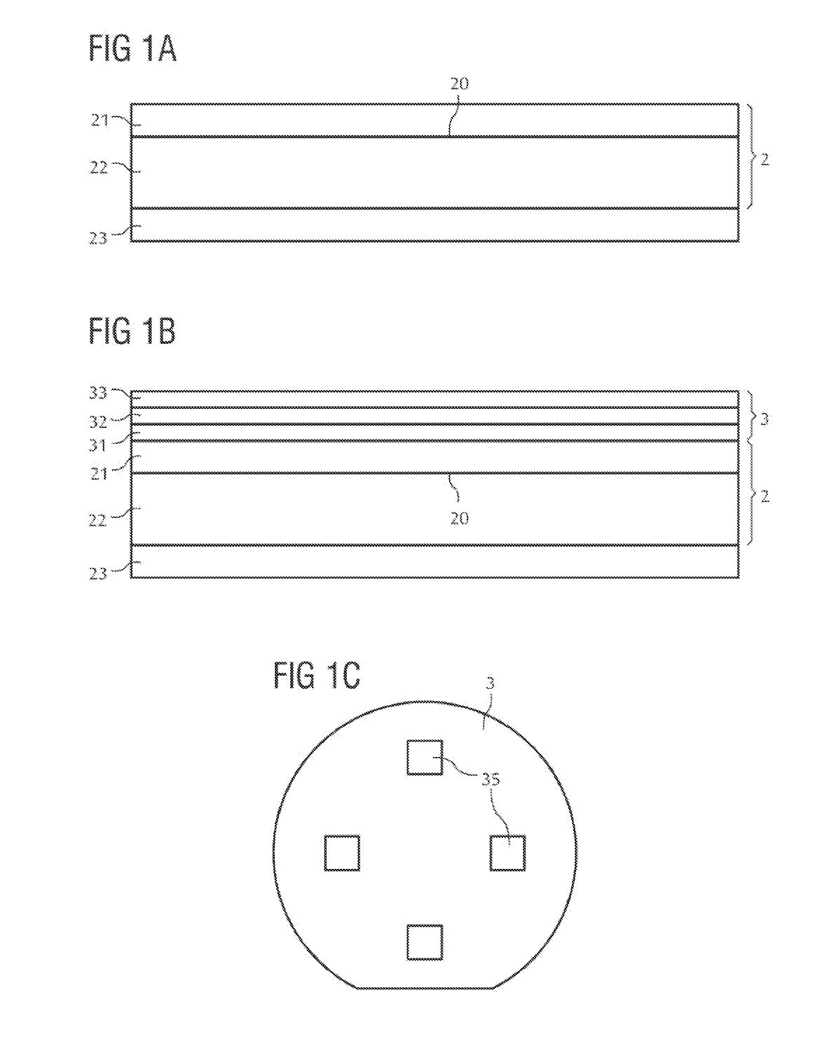

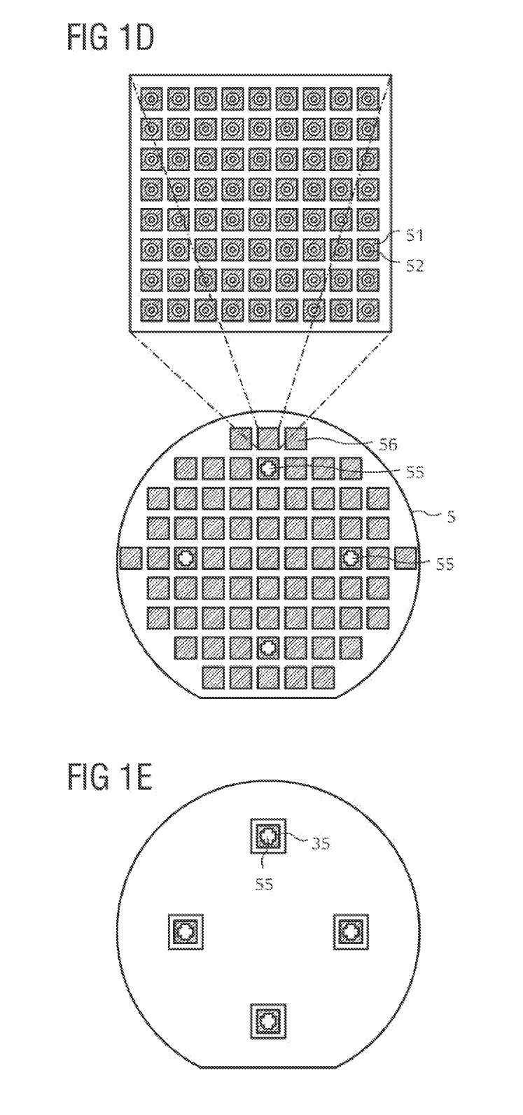

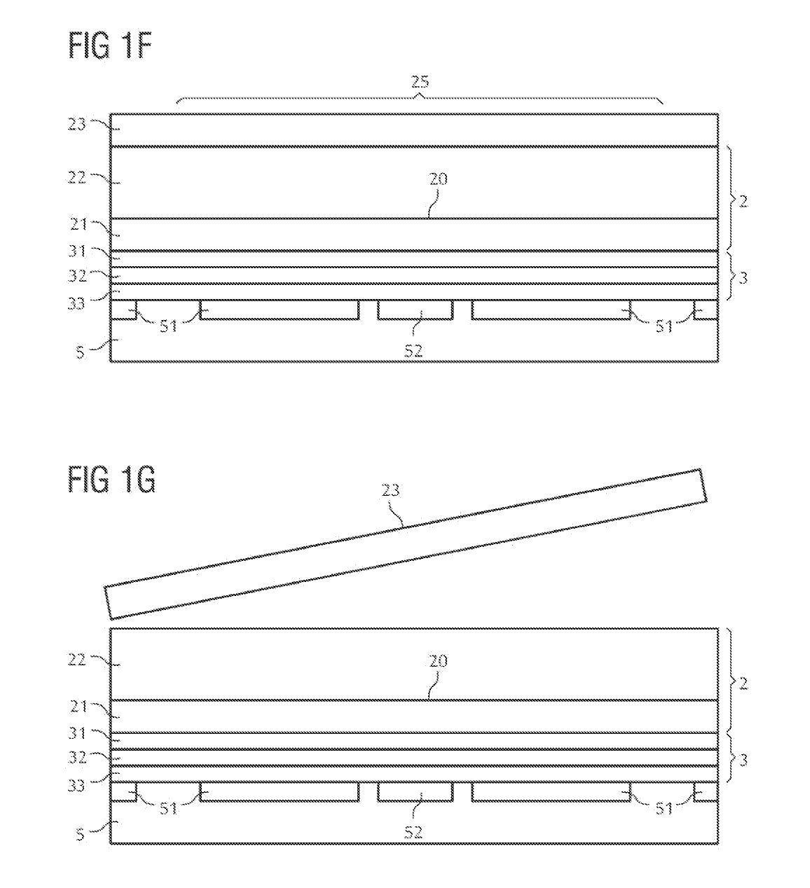

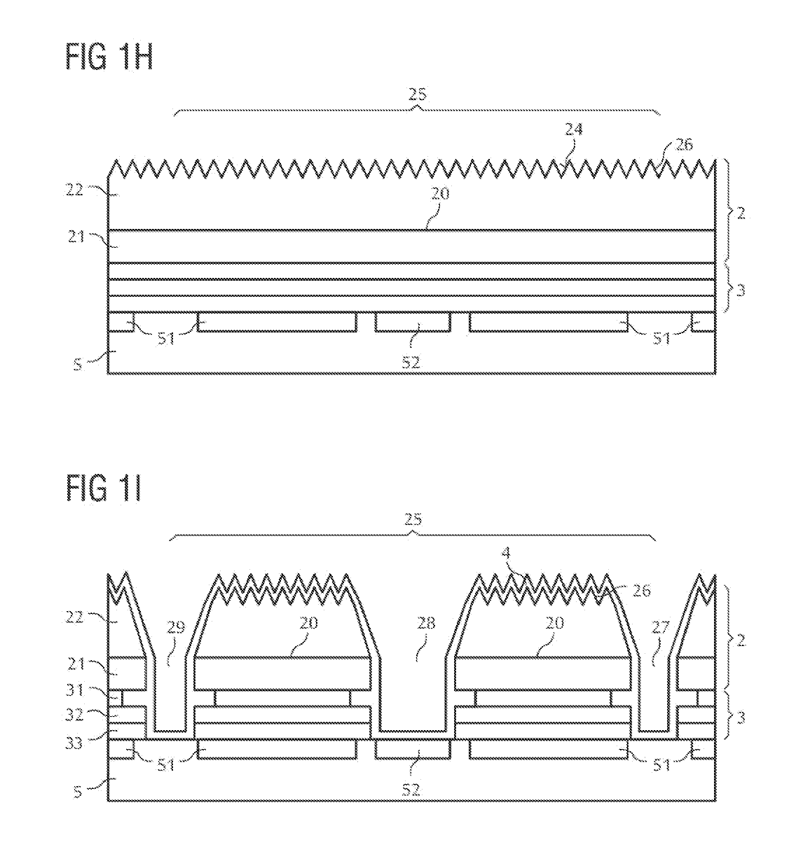

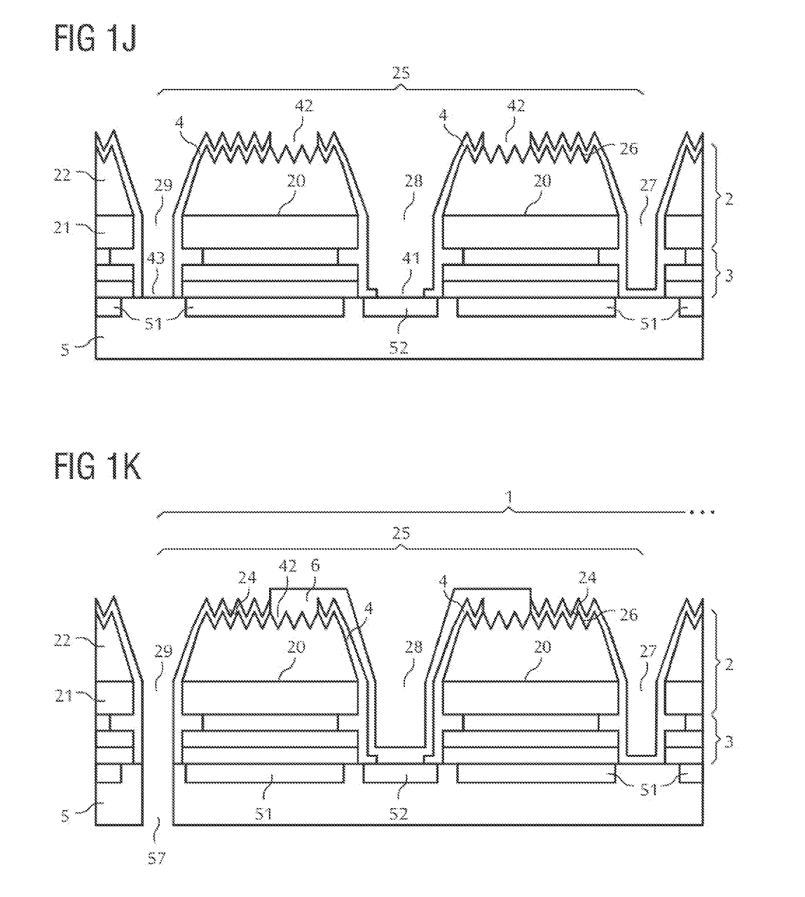

FIGS. 1A to 1K show a first exemplary embodiment of a method for producing optoelectronic semiconductor chips with the aid of intermediate steps, represented in schematic sectional view (FIGS. 1A, 1B and 1F to 1K) as well as in plan view (FIGS. 1C to 1E);

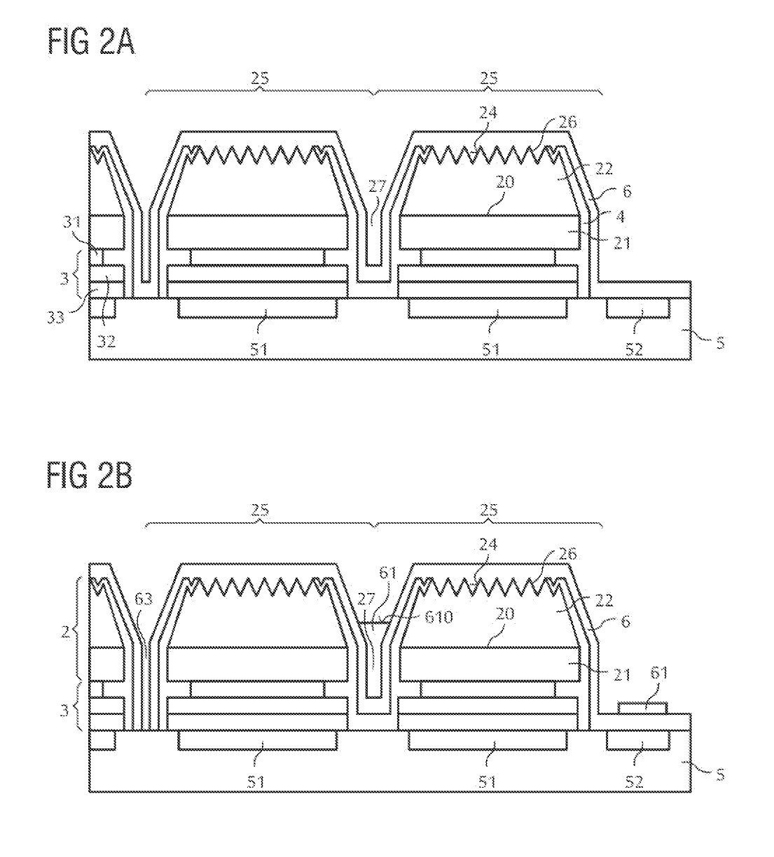

FIGS. 2A to 2C show a second exemplary embodiment of a method with the aid of intermediate steps represented in sectional view;

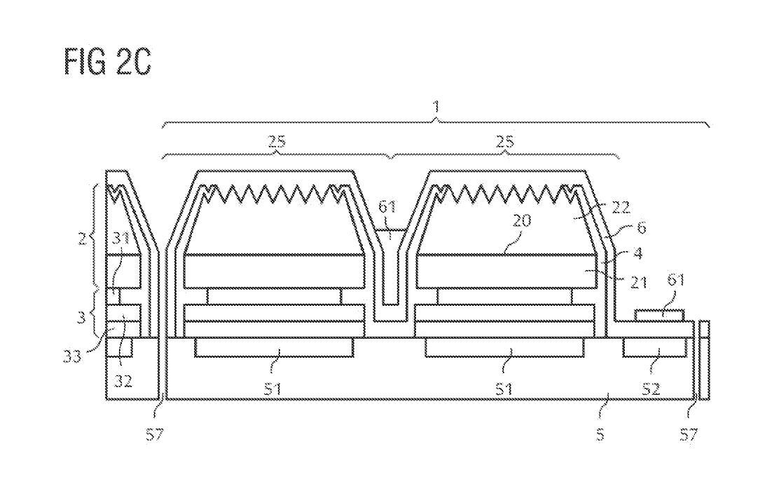

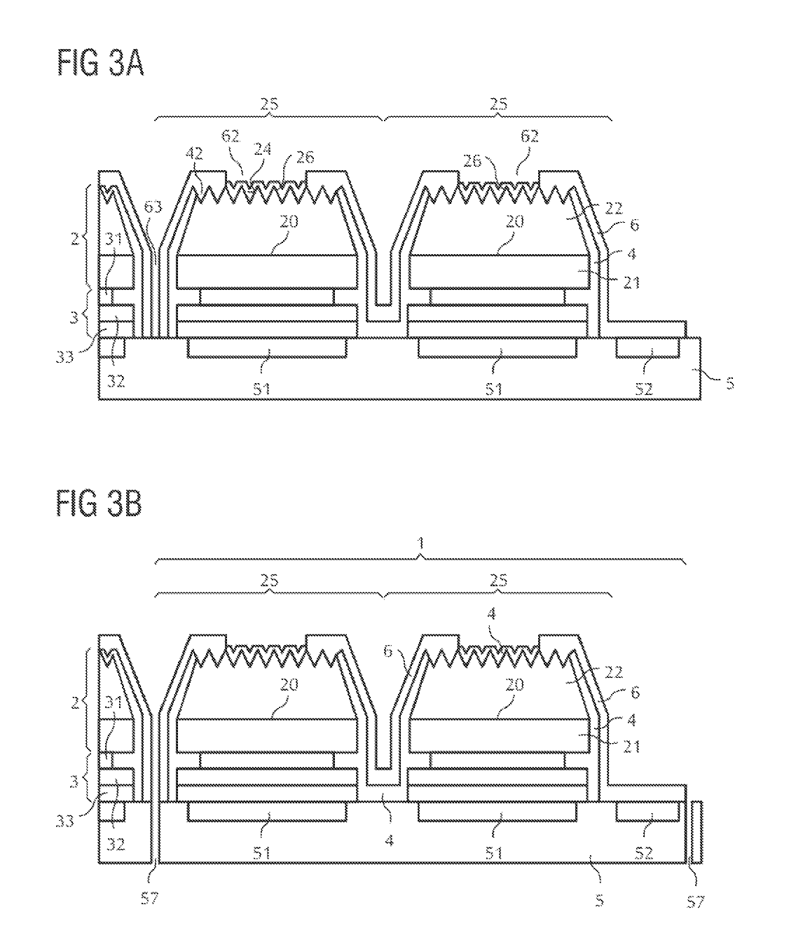

FIGS. 3A and 3B show a third exemplary embodiment of a method for producing optoelectronic semiconductor chips; and

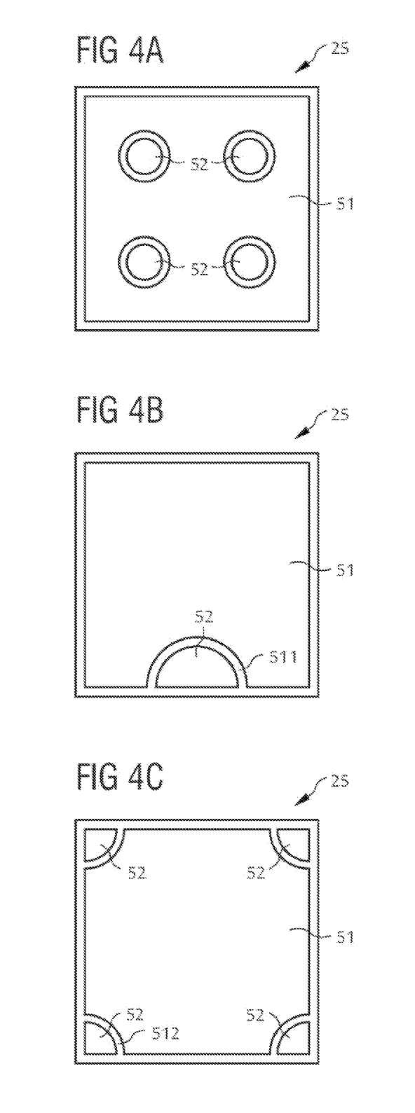

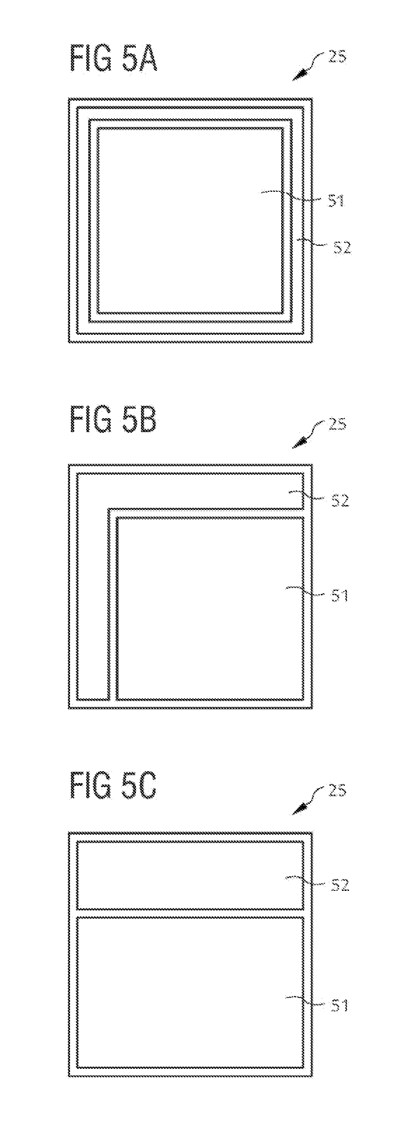

FIGS. 4A to 4C and 5A to 5C respectively show exemplary embodiments of the configuration of the connection surfaces on the carrier.

Elements which are the same or of the same type, or which have the same effect, are provided with the same references in the figures.

The figures and the size proportions of the elements represented in the figures with respect to one another are not to be regarded as true to scale. Rather, individual elements may be represented exaggeratedly large for better representability and/or for better understanding.

As represented in FIG. 1A, a semiconductor layer sequence 2 is provided, an active region 20, which is intended to receive and/or generate radiation, being provided between a p-conductive first semiconductor layer 21 and an n-conductive second semiconductor layer 22. The active region may, for example, be configured as a pn junction or as a multiple quantum well (MQW) structure.

The semiconductor layer sequence 2, in particular the active region 20, preferably contains a III-V compound semiconductor material. The semiconductor layer sequence may of course also be inverted in relation to the conduction type, that is to say the first semiconductor layer may be configured to be n-conductive and the second semiconductor layer may be configured to be p-conductive. The first semiconductor layer, the second semiconductor layer and the active region may respectively be formed in a plurality of layers. In order to simplify the representation, this is not explicitly shown. The semiconductor layer sequence is preferably deposited epitaxially on a growth substrate 23, for example by means of MOCVD or MBE.

After the end of the epitaxy, a metal interlayer is deposited on the side of the semiconductor layer sequence 2 facing away from the growth substrate 23, for example by means of vapor deposition or sputtering (FIG. 1B). In the exemplary embodiment shown, the metal interlayer is formed in a plurality of layers, and comprises by way of example a mirror layer 31 facing toward the semiconductor layer sequence 2, a barrier layer 32 and a connection metallization 33. For example, a layer which contains silver or consists of silver is suitable as the mirror layer. For example, a layer of titanium tungsten nitride is suitable as the barrier layer. Gold, for example, is suitable for the connection metallization. Other materials may, however, also be used; for example, rhodium is likewise distinguished by a high reflectivity in the visible spectral range. In this case, the barrier layer 32 may even be omitted.

The structure of the metal interlayer may be varied within wide limits in respect of the layer sequences, layer thicknesses and materials. For example, a layer containing a TCO material may be formed in the metal interlayer 3 or between the semiconductor layer sequence 2 and the metal interlayer 3.

The metal interlayer 3 is formed in such a way that it comprises alignment windows 35 (FIG. 1C). The alignment windows extend fully through the metal interlayer in the vertical direction.

As represented in FIG. 1F, the semiconductor layer sequence 2 with the metal interlayer 3 is fastened on a carrier 5. The fastening is preferably carried out by means of a bonding layer, for instance a solder layer or an electrically conductive adhesive layer (not explicitly represented in FIG. 1F).

Integrated into the carrier, there is a control circuit for the individual pixels, for instance an active matrix control circuit. The control circuit may, for example, be configured in CMOS technology in the carrier. For simplified representation, only a plurality of first connection surfaces 51 and second connection surfaces 52 are represented in the figures. In the exemplary embodiment shown, precisely one first connection surface 51 and one second connection surface 52 are provided for each pixel 25. The first connection surface 51 extends around the second connection surface 52 in the form of a frame. At the stage represented in FIG. 1F, the first semiconductor layer 21 is electrically conductively connected both to the first connection surfaces 51 and to the second connection surfaces 52. The first semiconductor layer thus connects the first connection surfaces to the second connection surfaces. Electrical separation is not carried out until a later stage of production.

As represented in FIG. 1D, in plan view the carrier has a plurality of chip regions 56 which are arranged next to one another. The chip regions are respectively provided for a finally produced semiconductor chip. Each chip region 56 has first connection surfaces 51 and second connection surfaces corresponding to the number of pixels of each semiconductor chip. In order to increase the reflectivity, the connection surfaces, in particular the second connection surfaces 52, may be provided with a coating. For example, rhodium is suitable for this because of its high reflectivity in the visible spectral range.

Alignment marks 55 are additionally formed on the carrier 5. The lateral extent of the alignment marks is less than the grid dimension with which the semiconductor chips are arranged, so that only one semiconductor chip is respectively lost for each alignment mark 55 during production. The alignment marks may, however, also be larger than the grid dimension with which the semiconductor chips are arranged. It is, of course, also conceivable to arrange the alignment marks in the edge region of the carrier, so that no area usable for semiconductor chips is lost.

Expediently, the center spacings of neighboring alignment marks are equal to the center spacings between the associated alignment windows 35.

When the semiconductor layer sequence 2 is being fastened on the carrier 5, the alignment windows 35 and the alignment marks 55 are positioned in such a way that the alignment marks 55 overlap with the alignment windows 35 and are preferably arranged fully inside the alignment windows (see FIG. 1E). The semiconductor layer sequence 2 itself is still entirely unstructured laterally during this alignment step, so that the requirements for the alignment accuracy are relatively low. In particular, the alignment tolerance during the positioning may even be greater than a center spacing between neighboring pixels. The required alignment accuracy is essentially dictated by the size of the alignment windows 35. The requirements for the alignment accuracy are particularly low when the alignment windows are significantly larger than the alignment marks.

After the semiconductor layer sequence 2 has been fastened on the carrier 5, the growth substrate 23 is removed as represented in FIG. 1G. In the case of a semiconductor layer sequence 2 based on a nitride compound semiconductor material, for instance AlₓIn_{y}Ga_{1-x-y}N with 0≦x≦1, 0≦y≦1 and x+y≦1, sapphire or silicon are for example suitable as the growth substrate. A mechanical method, for instance grinding, lapping or polishing, and/or a chemical method, for example wet or dry chemical etching, is for example suitable for the removal of the growth substrate. Depending on the material of the growth substrate, for example in the case of a sapphire growth substrate, a laser lift-off method is also suitable.

Unlike in the exemplary embodiment described, the growth substrate 23 may also be removed already before the semiconductor layer sequence 2 is fastened on the carrier 5. In this case, before fastening on the carrier 5, the semiconductor layer sequence is preferably fastened on an auxiliary carrier, which is removed after the semiconductor layer sequence 2 is fastened on the carrier 5.

A radiation transmission surface 24, facing away from the carrier 5, of the semiconductor layer sequence is provided with roughening 26, as represented in FIG. 1H. For example, a wet chemical etching method, for instance by means of KOH, is suitable for the formation of pyramidal or frustopyramidal depressions in the second semiconductor layer 22. The roughening is used for better radiation coupling-out in the case of a radiation-emitting semiconductor chip, or improved radiation coupling-in for the case of a radiation-receiving semiconductor chip. The roughening may be carried out over the entire surface of the semiconductor layer sequence 2. A photolithographic method is thus not necessary for this.

As represented in FIG. 1I, separating trenches 27, which define the individual pixels 25 of the semiconductor chips 1, are formed in the semiconductor layer sequence 2. The separating trenches preferably extend fully through the semiconductor layer sequence 2 and the metal interlayer 3 in the vertical direction. The first connection surfaces 51 of the pixels arranged next to one another, which are connected to one another by the metal interlayer 3 before the separating trenches 27 are formed, are electrically isolated from one another by the formation of the separating trenches 27.

In the same method step, cutouts 28 are formed, which likewise extend through the semiconductor layer sequence 2 and the interlayers 3. In the region of the cutouts 28, the second connection surfaces 52 are exposed. In addition, chip trenches 29, which separate the semiconductor layer sequences of the future individual semiconductor chips from one another, are formed in this production step. This ensures that only the material of the carrier 5 has to be cut through during the subsequent singulation of the semiconductor chips. The formation of the individual pixels by the formation of the separating trenches 27 is carried out by means of a photolithographic method, in which alignment relative to the alignment marks 55 on the carrier 5 is carried out. This step is the first finely adjusted photolithographic step of the method. Preferably, the alignment tolerance is at most half as great as the center spacing between two neighboring pixels 25.

In the region of the separating trenches 27, the material of the semiconductor layer sequence 2 is preferably removed by means of a wet chemical method. This results in oblique side edges, so that the cross section of the pixels 25 in the vertical direction decreases at least in regions with an increasing distance from the carrier 5. It is, however, also possible to use a different method, for example a dry chemical etching method or mechanical back sputtering for the formation of the separating trenches.

Subsequently, an insulation layer 4 is applied surface-wide onto the semiconductor layer sequence 2. As shown in FIG. 1J, the insulation layer 4 is structured by means of a second finely adjusted photolithographic method. The structured insulation layer comprises a connection opening 41, in which the second connection surface 52 is exposed. The insulation layer 4 furthermore comprises at least one contact opening 42, in which the second semiconductor layer 22 is exposed, for each pixel 25.

The insulation layer 4 furthermore comprises a trench opening 43. In this trench opening, the material of the carrier 5 is exposed for the singulation of the semiconductor chips. For example, an oxide, for instance silicon oxide or titanium oxide, a nitride, for example silicon nitride, or an oxynitride, for example silicon oxynitride, is suitable for the insulation layer. The insulation layer 4 is used, in particular, as a dielectric encapsulation for protecting the semiconductor layer sequence 2 and the metal interlayer 3 against moisture. For example, degradation of a mirror layer containing silver can be avoided in this way.

As represented in FIG. 1K, a contact layer 6 is formed, which electrically conductively connects the second connection surface 52 in the region of the contact opening 42 to the second semiconductor layer 22. The contact layer 6 covers the radiation transmission surface 24 in regions. On the side edges of the cutout 28, in particular at the height of the active region 20, the insulation layer 4 is arranged between the contact layer 6 and the semiconductor layer sequence 2 in order to avoid an electrical short circuit. In particular, a TCO material, for instance ITO, ZnO or SnO₂, is suitable for the contact layer 6. In this way, shadowing of the radiation transmission surface 24 can be avoided. As an alternative or in addition, a metal may also be used for the contact layer 6. The structuring of the contact layer 6 is carried out by means of a third finely adjusted photolithographic process.

Singulation of the wafer assembly with the carrier 5 and the semiconductor layer sequence 2 into individual semiconductor chips 1 is subsequently carried out along the chip trenches 29. To this end, a singulation trench 57 which extends fully through the carrier is formed. For example, a sawing method or a laser cutting method is suitable for the singulation.

With the described method, semiconductor chips, each of which comprises a plurality of pixels, can be produced with only three finely adjusted photolithographic processes, the pixels respectively being contactable and drivable individually by means of an active matrix circuit.

In particular, elaborate and error-susceptible fine adjustment of a semiconductor layer sequence already prestructured into pixels relative to a carrier with a driver circuit is not necessary. Contrary to the conventional procedure, a per se undesired electrically conductive connection between the first connection surface 51 and the second connection surface 52 occurs when fastening the semiconductor layer sequence 2 over the first semiconductor layer 21. The electrical separation required for operation is not carried out until after fastening on the carrier. Furthermore, all the finely adjusted fabrication steps can be carried out after the semiconductor layer sequence 2 is already fastened on the carrier 5.

The semiconductor chip 1 finally produced by the singulation is shown as a detail in FIG. 1K. The semiconductor chip is suitable for example for a display device, for an adaptive headlamp system or for a camera light of a cellphone or a camera.

In the exemplary embodiment shown, the second connection surface 52 is arranged centrally inside the first connection surface 51. In the case of a central arrangement of the second connection surface, uniform current supply to the second semiconductor layer 22 can take place in a simple manner.

Alternative configurations of the first connection surface 51 and the second connection surface 52 are shown in FIGS. 4A to 4C and 5A to 5C. In the exemplary embodiment represented in FIG. 4A, each pixel 25 comprises a plurality of second connection surfaces 52. The second connection surfaces 52 can thus be made smaller in terms of their cross section in comparison with a single connection surface. In comparison with a single central contact surface, the risk of a perturbing dark region occurring in the middle of the pixels is thus reduced. Such a dark region may, in particular, be perturbing when imaging optics are arranged after the semiconductor chip 1 in the emission direction.

In the exemplary embodiment represented in FIG. 4B, the second connection surface 52 is arranged in an edge region 511 of the first connection surface 51. In this configuration, a darker region occurs only on an edge of the pixel 25. However, this can lead to a relatively nonuniform current supply to the pixels 25 in the lateral direction.

In order to avoid a nonuniform current supply, in the exemplary embodiment represented in FIG. 4C the second connection surfaces 52 are respectively arranged in the corner regions 512 of the first connection surface 51. It is, however, also sufficient for a second connection surface 52 to be provided not in all corner regions, but for example only in one corner or only in two corners.

In the variant represented in FIG. 5A, the second contact surface 52 extends around the first contact surface 51 along the entire circumference. In this way, a homogeneous current supply can be achieved without a darker central region of the pixels 25. However, this configuration requires particularly high alignment accuracies and a particularly high level of structural precision.

These requirements can be reduced if the second connection surface 52 does not extend along all the edges of the first connection surface 51. In FIG. 5B, the second connection surface 52 is configured in an L-shape and extends along two edges of the first connection surface 51. In the exemplary embodiment according to FIG. 5C, the first connection surface 51 and the second connection surface 52 are arranged next to one another, so that the second connection surface extends only along one edge of the first connection surface.

A second and a third exemplary embodiment of a method for producing optoelectronic semiconductor chips are respectively shown in FIGS. 2A to 2C and 3A and 3B with the aid of intermediate steps represented schematically in sectional view. These two further exemplary embodiments differ from the first exemplary embodiment essentially by the nature of the contacting of the second semiconductor layer 22.

In particular, the fastening of the semiconductor layer sequence 2 on the carrier 5 may be carried out as described in connection with FIGS. 1H to 1I. In the further exemplary embodiments, the carrier 5 differs merely in that each semiconductor chip 1 comprises only one second connection surface 52, which is electrically conductively connected to all the pixels 25.

To this end, as represented in FIG. 2A, a contact layer 6 is applied surface-wide on the semiconductor layer sequence 2. On the radiation transmission surface 24, at least in regions the contact layer adjoins the radiation transmission surface 24 and is electrically conductively connected to the second semiconductor layer 22. As represented in FIG. 2B, the contact layer 6 is structured so that, at the position where the singulation of the semiconductor chips subsequently takes place, a trench opening 63 of the contact layer is formed. In order to improve the transverse conductivity of the contact layer 6, a metal layer 61 is formed in the separating trenches 27 between neighboring pixels. Furthermore, the metal layer may also extend along the edge regions of the semiconductor chips. A surface 610, facing away from the carrier 5, of the metal layer 61 extends between the carrier 5 and the radiation transmission surface 24 in the vertical direction. The metal layer thus does not cover the radiation transmission surface 24. In addition to the improved transverse conductivity, optical crosstalk between the pixels can be reduced by means of the metal layer 61 in the separating trenches 27 between the pixels 25.

The singulation of the semiconductor chips may be carried out as described in connection with the first exemplary embodiment. A finally produced semiconductor chip 1 is shown in FIG. 2C.

The third exemplary embodiment, represented in FIGS. 3A and 3B, likewise has a common contact layer 6 for all the pixels 25 of a semiconductor chip 1. In contrast to the second exemplary embodiment, the contact layer 6 is formed in one layer as a metal layer. For radiation output, the contact layer 6 respectively has a radiation window 62 on the radiation transmission surfaces 24 of the semiconductor chips. In the region of the radiation window, the radiation transmission surface 24 is thus free of metallic material, so that the radiation windows respectively define that region of the pixels from which the radiation generated during operation emerges, or in which the radiation to be detected enters. A finally produced semiconductor chip according to the third exemplary embodiment is shown in FIG. 3B.

This patent application claims the priority of German Patent Application 10 2012 112 530.9, the disclosure content of which is hereby incorporated by reference.

By the description with the aid of the exemplary embodiments, the invention is not restricted to these exemplary embodiments. Rather, the invention covers any new feature and any combination of features, which includes in particular any combination of features in the patent claims, even if this feature or this combination is not explicitly indicated per se in the patent claims or the exemplary embodiments.

1. A method for producing a plurality of optoelectronic semiconductor chips, each of which comprises a plurality of pixels, having the steps:
a) providing a semiconductor layer sequence having an active region intended to generate and/or detect radiation, which is formed between a first semiconductor layer and a second semiconductor layer;
b) providing a carrier having a plurality of first connection surfaces;
c) fastening the semiconductor layer sequence on the carrier, so that the first semiconductor layer is electrically conductively connected to the first connection surfaces;
d) forming separating trenches in the semiconductor layer sequence which is fastened on the carrier in order to form the pixels, the separating trenches extending through the semiconductor layer sequence;
e) forming a contact layer, which connects the second semiconductor layer electrically conductively to a second connection surface of the carrier; and
f) singulating the carrier into the plurality of semiconductor chips, each of which comprises a plurality of pixels.

2. The method according to claim 1,
wherein the semiconductor layer sequence is free of recesses in the region of the semiconductor chips in step c).

3. The method according to claim 1,
wherein alignment is carried out relative to alignment marks, which are formed on the carrier, during the formation of the separating trenches.

4. The method according to claim 1,
wherein the semiconductor layer sequence is provided with a metal interlayer before step c).

5. The method according to claim 4,
wherein the metal interlayer is cut through between step c) and step f).

6. The method according to claim 1, wherein
the semiconductor layer sequence is provided with a metal interlayer before step c);
alignment windows are formed in the metal interlayer before step c); and
the semiconductor layer sequence is positioned relative to the carrier in step c) so that alignment marks on the carrier overlap with the alignment windows.

7. The method according to claim 1, wherein the semiconductor layer sequence is deposited epitaxially on a growth substrate, and the growth substrate is removed before step d).

8. An optoelectronic semiconductor chip having a semiconductor layer sequence that comprises an active region intended to generate and/or receive radiation, which is arranged between a first semiconductor layer and a second semiconductor layer, wherein
the semiconductor layer sequence is subdivided into a plurality of pixels;
the semiconductor chip comprises a carrier, on which the semiconductor layer sequence is arranged and which comprises a driver circuit for the individual pixels;
the carrier comprises, for each pixel, a first connection surface which is electrically conductively connected to the first semiconductor layer of the pixels; and
the second semiconductor layer is connected electrically conductively to a second connection surface by a contact layer, the contact layer covering a radiation transmission surface facing away from the carrier at least in regions.

9. The semiconductor chip according to claim 8,
wherein the pixels of the semiconductor layer sequence taper at least in regions with an increasing distance from the carrier.

10. The semiconductor chip according to claim 8,
wherein the second semiconductor layer of each pixel is respectively connected electrically conductively by the contact layer to at least one second connection surface assigned to the pixel.

11. The semiconductor chip according to claim 8,
wherein the first connection surface extends around the at least one second connection surface.

12. The semiconductor chip according to claim 8, wherein the at least one second connection surface is arranged in an edge region or in a corner region of the first connection surface.

13. The semiconductor chip according to claim 8, wherein the first connection surface extends along at least two edges of the second connection surface.

14. The semiconductor chip according to claim 8, wherein each pixel comprises at least one cutout in the semiconductor layer sequence, and the contact layer extends from the second connection surface through the cutout to the second semiconductor layer.

15. The semiconductor chip according to claim 8,
wherein the second semiconductor layers of at least two neighboring pixels are electrically conductively connected to one another by the contact layer.

16. The semiconductor chip according to claim 8, wherein the pixels are separated from one another by separating trenches, and the contact layer extends in regions in the separating trenches.

17. The semiconductor chip according to claim 16,
wherein the contact layer comprises a metal layer, which extends in the form of a grid in the separating trenches.

18. The semiconductor chip according to claim 8, wherein the contact layer comprises a TCO material.

19. (canceled)

20. An optoelectronic semiconductor chip having a semiconductor layer sequence that comprises an active region intended to generate and/or receive radiation, which is arranged between a first semiconductor layer and a second semiconductor layer, wherein
the semiconductor layer sequence is subdivided into a plurality of pixels;
the semiconductor chip comprises a carrier, on which the semiconductor layer sequence is arranged and which comprises a driver circuit for the individual pixels;
the carrier comprises, for each pixel, a first connection surface which is electrically conductively connected to the first semiconductor layer of the pixels;
the second semiconductor layer is connected electrically conductively to a second connection surface by a contact layer, the contact layer covering a radiation transmission surface facing away from the carrier at least in regions; and
the first connection surface extends around the at least one second connection surface or along at least two edges of the second connection surface.
